(19) United States
(12) Patent Application Publication
(10) Pub. No.: US 2005/0189651 A1
(43) Pub. Date: Sep. 1, 2005

(54) Contact formation method and semiconductor device

(75) Inventors: Yutaka Hirose, Nagaokakyo-shi (JP); Yoshito Ikeda, Ibaraki-shi (JP); Kaoru Inoue, Ootsu-shi (JP)

Correspondence Address: PARKHURST & WENDEL, L.L.P., 1421 PRINCE STREET, SUITE 210, ALEXANDRIA, VA, 22314-2805, US

(73) Assignee: MATSUSHITA ELEC. IND. CO. LTD., Kadoma-shi (JP)

(21) Appl. No.: 10/625,546

(22) Filed: Jul. 24, 2003

(30) Foreign Application Priority Data
Jul. 25, 2002 (JP) 2002-216296

(51) Int. Cl. H01L 23/48

(52) U.S. Cl. 257/745

(57) ABSTRACT

An object of the present invention is to reduce the resistance of an electrode of a Group III nitride semiconductor. A thin Si film and a thin Ti film are formed selectively in a contact formation region on a surface of an AlGaN layer as a Group III nitride semiconductor layer formed on a substrate, and the resulting substrate is heat-treated at a high temperature. By the heat treatment, Si is diffused into the AlGaN layer in the ohmic contact formation region at a concentration of about 10²⁰ cm³. Further, an electron density sufficiently high to provide an ohmic characteristic through a reaction between Si and Ti is provided. Thus, a low resistance TiSi₂ portion resulting from the reaction between Si and Ti, a TiN portion resulting from a reaction between Ti and AlGaN and a Group III metal portion of Ga and Al devoid of nitrogen are formed in the contact formation region thereby to provide a low resistance electrode film mainly comprising TiSi₂.

### FIELD OF THE INVENTION

The present invention relates to a contact formation method for forming a contact for a light emitting device such as a semiconductor laser for emitting bluish purple light and a high frequency power device by employing a Group III nitride semiconductor, and to a semiconductor device.

### BACKGROUND OF THE INVENTION

Group III nitride semiconductors represented by a general formula B_{z}AlₓGa_{1-x-y-z}InyN (0≦x≦−1, 0≦y≦1, 0≦z≦1) generally have abroad direct transition band gap, and are increasingly employed as materials for short wavelength optical devices. The Group III nitride semiconductors are high in electron saturation velocity, insulator resistance and heat conductivity and, hence, applications thereof to high frequency power devices are now under consideration.

There is known a method for forming a contact having an excellent ohmic characteristic (hereinafter referred to simply as “ohmic contact”) in an n-type region in an optical/electronic device employing a Group III nitride semiconductor (S. J. Pearton et al., Journal of Applied Physic, Vol. 86(1999), p1-p78; Zhi Fan et al., Applied Physics Letters Vol. 68(1996), p1672-p1674).

In this ohmic contact formation method, as shown in FIG. 7(a), a Ti film 33, an Al film 34 and an Au film 35 are formed in a contact formation region on a surface of an n-type region 32 of a nitride semiconductor 31, and then a heat treatment is performed at 500 to 700° C.

FIG. 7(b) schematically illustrates a contact region as microscopically observed after the heat treatment. The heat treatment causes Ti to react with the nitride semiconductor 31 in the n-type region 32 to form electrically conductive TiN portions 36. Accordingly, nitrogen voids 37 are formed in the nitride semiconductor 31, and metal portions 38 of Group III metals devoid of nitrogen are formed in the nitride semiconductor 31. On the other hand, Al on the Ti film 33 is diffused into the nitride semiconductor 31, and low resistance metal portions 39 mainly comprising Au remains in a surface portion. As a result, the nitrogen voids 37 contribute as a defect level to the electrical conductivity. Further, the diffused Al, the TiN portions 36 and the metal portions 38, 39 contribute to the electrical conductivity. Therefore, a lower resistance region 40 is formed in the n-type region 32.

A high electron mobility transistor (hereinafter referred to as “HEMT”) is known which includes ohmic contacts formed in the aforesaid manner in source/drain regions.

In order to form excellent ohmic contacts in the aforesaid manner, surface portions of a nitride semiconductor on which metal electrodes are to be formed should be doped with an impurity at a high concentration. In the case of the HEMT, contact formation regions each have an AlGaN/GaN heterojunction structure, and the high speed operation of the HEMT can be achieved by accelerating a high-density and high-mobility two-dimensional electron gas present in the vicinity of the interface of the heterojunction by an external electric field applied between the source/drain regions. For the high speed operation, it is necessary to form the Ti film 33, the Al film 34 and the Au film 35 directly on the uppermost AlGaN layer (the nitride semiconductor 31 in the n-type region 32) and cause Al on the Ti film 33 to diffuse into the AlGaN layer to a depth sufficient to reach the two-dimensional electron gas in the heterojunction interface. The impurity necessary for the diffusion is typically introduced in the nitride semiconductor during the crystal growth of the semiconductor.

However, it is often impossible to introduce a necessary and sufficient amount of the impurity into the semiconductor during the crystal growth due to structural and functional limitations of the device. In the case of the HEMT, for example, the density of the two-dimensional electron gas in the heterojunction interface and the potential of the heterojunction interface are determined by the uppermost AlGaN layer. Therefore, the impurity concentration distribution and the permissible maximum impurity concentration observed just below a gate do not generally reach an impurity concentration level necessary to provide a proper ohmic characteristic in the source/drain regions. For this reason, Al (light element) is employed as a diffusion seed. However, it is difficult to control the rate of a reaction between Al and AlGaN and the rate of the diffusion of Al in AlGaN. If the reaction rate is high, an insulative AlN layer may be formed, thereby disadvantageously increasing the contact resistance.

It is also conceivable to employ Si as the diffusion seed. Where Si is deposited alone on the AlGaN layer, however, the heat treatment should be performed in a hydrogen atmosphere for diffusion of Si. This entails a great risk. In order to avoid the heat treatment in the hydrogen atmosphere, the Si film may be covered with a mask. However, an SiN film suitable as the mask is liable to be cracked and separated from the Si film because of its high thermal expansion coefficient, and the adjustment of the thickness of the SiN film is difficult. Since the cracking and separation of the SiN film are particularly liable to occur in an oxidative atmosphere, it is necessary to perform the heat treatment in a nitrogen atmosphere. However, the provision of a 100% pure nitrogen atmosphere is difficult. Further, excess silicon, which remains after the heat treatment, should be removed by hydrofluoric/nitric acid. This may result in the residence of Si and the roughening of the AlGaN layer.

In order to solve the aforesaid problems, it is an object of the present invention to provide a contact formation method which provides an excellent ohmic characteristic by facilitating the introduction of a sufficient amount of an impurity into a Group III nitride semiconductor layer, and to provide a semiconductor device.

### DISCLOSURE OF THE INVENTION

To attain the aforesaid object, the contact formation method according to the present invention comprises: forming a film comprising Si and Ti on a surface of a layer of a Group III nitride semiconductor; and heat-treating the film and the semiconductor layer. Thus, Si present in the vicinity of the Group III nitride semiconductor layer can sufficiently be diffused as an n-type impurity into the semiconductor layer, and activated by the heat treatment. In addition, Ti and Si react with each other to form TiSi₂ having a low resistance by the heat treatment, whereby a low resistance electrode film mainly comprising TiSi₂ is formed. Since Si and Ti are completely consumed by the formation of the electrode film and the diffusion of Si, the process for removing excess Si and Ti can be obviated.

The film formation preferably comprises depositing Si and Ti in this order. A heat treatment temperature for the heat treatment is preferably in the range of 500° C. to 1100° C. By employing the film deposition order and the heat treatment temperature described above, TiSi₂ of phase C54 having a low resistance can easily be formed, and Si can be diffused into the Group III nitride semiconductor layer at a sufficiently high rate.

The semiconductor device according to the present invention comprises: a Group III nitride semiconductor layer into which Si is diffused as an impurity by a heat treatment performed after a film comprising Si and Ti is formed on a surface of the Group III nitride semiconductor layer; and an electrode film of TiSi₂ formed by a reaction between Ti and Si. Thus, the semiconductor device has a contact having a low resistance and an excellent ohmic characteristic.

### BRIEF DESCRIPTION OF THE DRAWINGS

FIG. 1 is a sectional view of a semiconductor device according to a first embodiment of the present invention;

FIGS. 2(a) and 2(b) are sectional views for explaining a contact formation process for the semiconductor device of FIG. 1;

FIGS. 3(a) and 3(b) are diagrams respectively illustrating I-V characteristics of a semiconductor device having contacts formed by the method shown in FIGS. 2(a) and 2(b) and a semiconductor device having contacts formed by a conventional method;

FIG. 4 is a sectional view of a semiconductor device according to a second embodiment of the present invention;

FIG. 5 is a sectional view for explaining a contact formation process for the semiconductor device of FIG. 4;

FIGS. 6(a) and 6(b) are diagrams respectively illustrating I-V characteristics of a semiconductor device having contacts formed by the method shown in FIG. 5 and a semiconductor device having contacts formed by the conventional method; and

FIGS. 7(a) and 7(b) are sectional views for explaining a contact formation process for a conventional semiconductor device.

### EMBODIMENTS

Embodiments of the present invention will hereinafter be described with reference to the attached drawings.

### First Embodiment

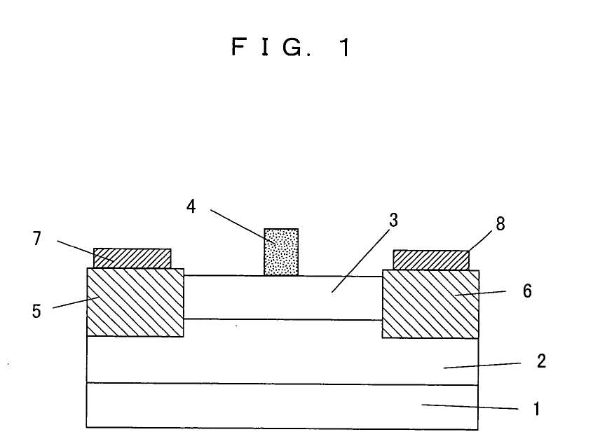

FIG. 1 is a sectional view of a semiconductor device according to a first embodiment of the present invention, particularly, a high electron mobility transistor (HEMT) having an AlGaN/GaN heterojunction.

In FIG. 1, there are shown a substrate 1, an intrinsic GaN layer 2, and an AlGaN layer 3 which forms a heterojunction cooperatively with the GaN layer 2. A two-dimensional electron gas is present in a heterojunction interface between the AlGaN layer 3 and the GaN layer 2. The substrate 1 is composed of a material selected from sapphire, SiC, LiAlO₂, LiGaO₂ and the like.

In FIG. 1, there are also shown a gate electrode 4, a source 5, a drain 6, a source electrode 7 and a drain electrode 8. The transistor is connected to an external device through the source electrode 7 and the drain electrode 8. The gate electrode 4 controls the amount of an electric current flowing from the source 5 to the drain 6.

An explanation will be given to a source/drain contact formation method for production of the aforesaid semiconductor device.

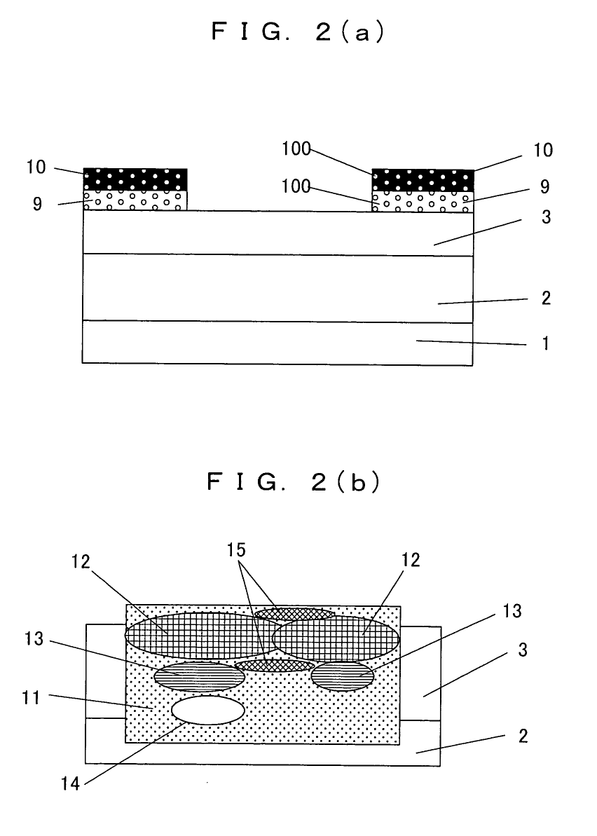

As shown in FIG. 2(a), a thin Si film 9 and a thin Ti film 10 are formed in this order selectively in contact formation regions in which ohmic contacts are to be formed on the AlGaN layer 3 by an electron beam evaporation method. In turn, the substrate 1 formed with these films 9, 10 is annealed at a high temperature (about 970° C.) in a 100% nitrogen atmosphere for about 5 minutes.

FIG. 2(b) schematically illustrates the contact formation region 11 (corresponding to the source 5 or the drain 6 in FIG. 1) as microscopically observed after the high temperature heat treatment.

By the high temperature heat treatment, Si of the thin Si film 9 (hereinafter referred to simply as “Si”) is diffused as an n-type impurity into the AlGaN layer 3 (hereinafter referred to simply as “AlGaN”) and activated. Thus, Si is present at a concentration of about 10²⁰ cm⁻³ in the contact formation regions 11. Further, an electron density sufficiently high to provide an ohmic contact characteristic through a reaction between Si and Ti of the thin Ti film 10 (hereinafter referred to simply as “Ti”) is provided. Thus, Si present in the vicinity of the thin Ti film 10 reacts with Ti to form low resistance TiSi₂ portions 12. Further, Ti reacts with AlGaN to form electrically conductive TiN portions 13. Accordingly, nitrogen voids 14 are formed, and Group III metal portions 15 constituted by Ga and Al devoid of nitrogen are formed.

As a result, the nitrogen voids 14 contribute as a defect level to the electrical conductivity, and the TiSi₂ portions 12, the TiN portions 13 and the Group III metal portions 15 contribute to the electrical conductivity.

Since Si is diffused as the impurity, no reaction with AlGaN occurs. Therefore, generation of an insulative substance can be avoided which may otherwise occur when a light metal such as Al is employed as a diffusion seed in an prior art. Where Si is employed as the diffusion seed, there is a need for a heat treatment in a hydrogen atmosphere or a need for a mask such as of an SiN film and a 100% pure nitrogen atmosphere in the prior art. According to this embodiment, on the contrary, the thin Ti film 10 functions as a mask, so that the hydrogen atmosphere, the additional mask and the strictly 100%-pure nitrogen atmosphere are not required.

The thin Si film 9 and the thin Ti film 10 initially formed on the AlGaN layer 3 are completely consumed for the formation of the TiSi₂ portions 12 and the TiN portions 13 and the diffusion of Si, so that the need for the process for removing excess Si and Ti can be obviated. Therefore, there is no fear of the residence of Si and the roughening of AlGaN layer which may otherwise occur after the removal process in the prior art.

Thus, the contact formation regions 11 each have an excellent low resistance ohmic characteristic.

The method according to the first embodiment provides source/drain contacts each having a lower resistance and a more excellent ohmic characteristic than a conventional method through a process sequence with substantially the same number of process steps as that of the conventional method.

In order to ensure sufficient diffusion of Si for the prevention of the residence of excess Si on the AlGaN layer 3, the thin Si film 9 should be formed to a sufficiently great thickness. Where the thin Si film 9 and the thin Ti film 10 each have a thickness of 3000 Å, for example, Si present in the vicinity of the interface between the AlGaN layer 3 and the thin Si film 9 can be diffused into the AlGaN layer 3 before the reaction with the thin Ti film 10 begins. Where the thin Ti film 10 has the aforesaid thickness, excess Ti not reacted with Si is consumed for the reaction with AlGaN.

As the proportion of Al in the AlGaN layer 3 is increased, the diffusion of Si in the AlGaN layer 3 becomes more difficult. In consideration of this fact, it is more preferred that the thin Si film 9 has a thickness of about 50 Å to about 100 Å and the thin Ti film 10 has a thickness of about 100 Å to about 500 Å, where the AlGaN layer 3 contains Al in a proportion of 25% and has a thickness of 250 Å.

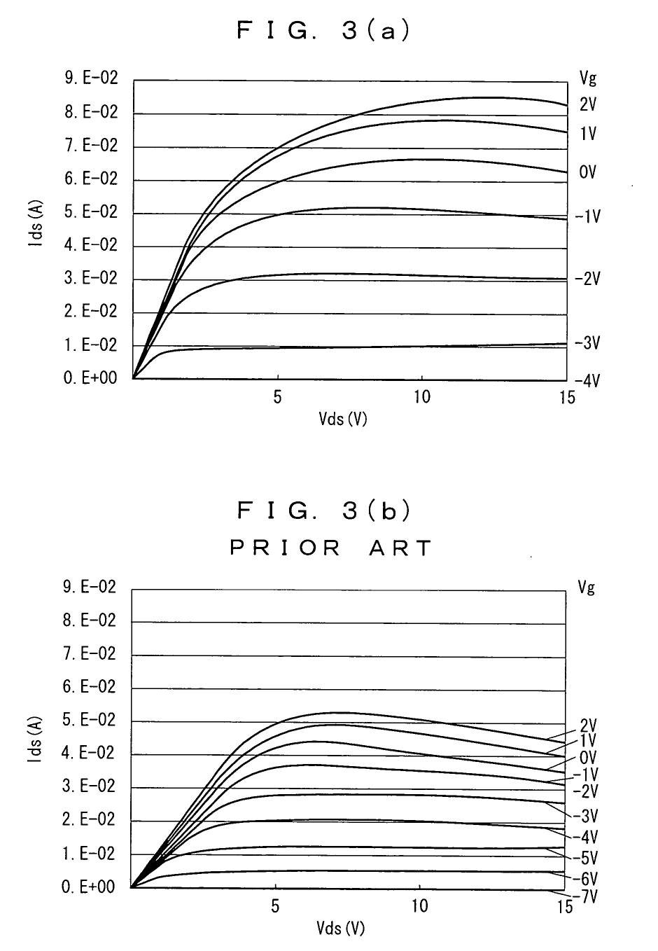

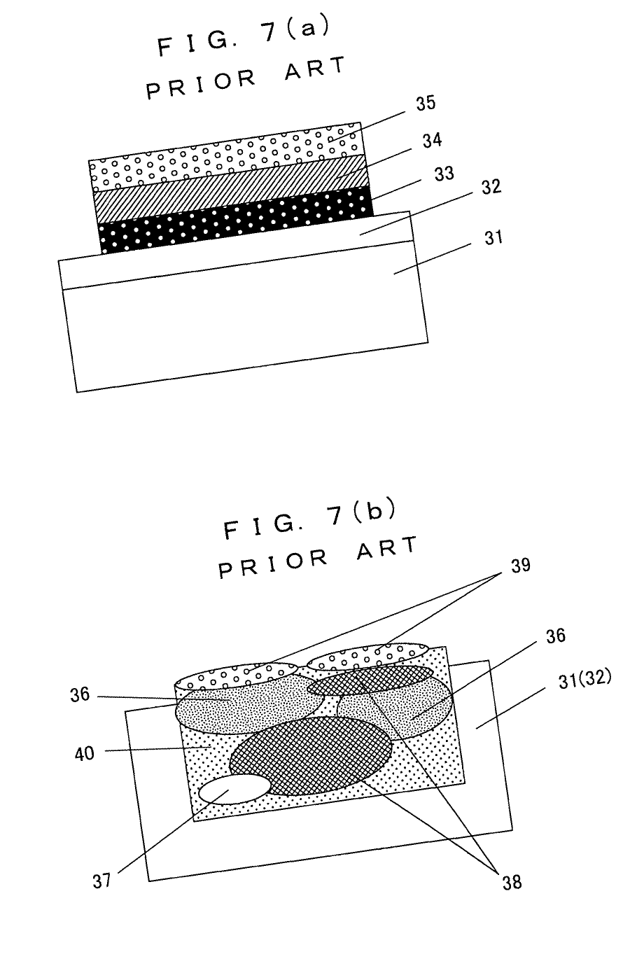

FIG. 3(a) illustrates an I-V characteristic of an HEMT having source/drain contacts formed by the method according to the first embodiment, and FIG. 3(b) illustrates an I-V characteristic of an HEMT having source/drain contacts formed by the conventional method (see FIG. 7).

As for the HEMT having the I-V characteristic shown in FIG. 3(a), the thickness of the substrate is 400 μm, the thickness of the GaN layer is 2 μm, the thickness of the AlGaN layer (Al/Ga=0.25/0.75) is 25 nm, the thickness of the thin Si film is 100 Å, the thickness of the thin Ti film is 100 Å, and the contact resistance is 3×10⁻⁶ Ωcm².

As for the HEMT having the I-V characteristic shown in FIG. 3(b), the thickness of the substrate is 400 μm, the thickness of the GaN layer is 2 μm, the thickness of the AlGaN layer (Al/Ga=0.25/0.75) is 25 nm, the thickness of the Ti film is 200 Å, the thickness of the Al film is 2000 Å, the thickness of the Au film is 2000 Å, and the contact resistance is 2×10⁻⁵ Ωcm². The substrate and the film formation regions of the HEMT of FIG. 3(b) have the same dimensions as those of the HEMT of FIG. 3(a).

As apparent from FIGS. 3(a) and 3(b), the HEMT according to the first embodiment is more excellent in output characteristics with a lower resistance in a linear area at the same gate voltage and with a higher drain electric current in a saturated area than the conventional HEMT.

### Second Embodiment

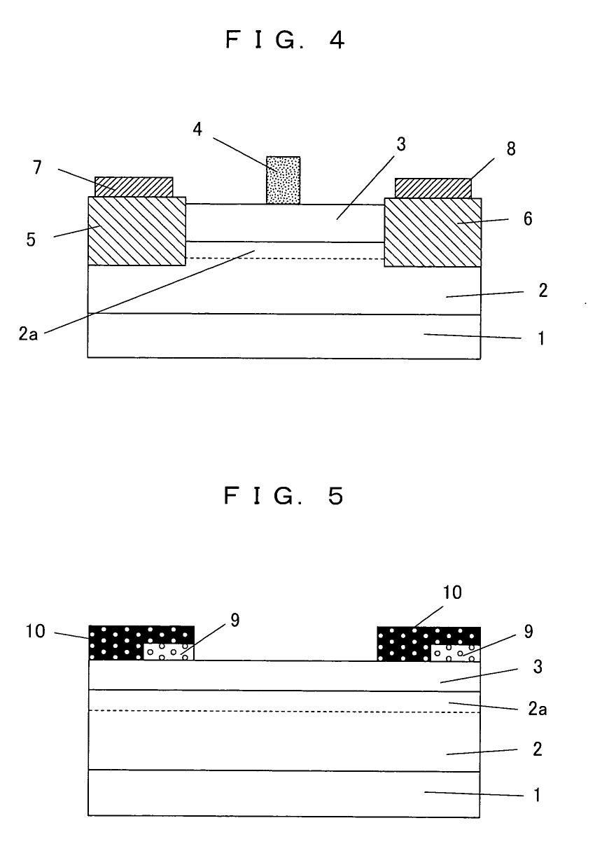

FIG. 4 is a sectional view of a semiconductor device according to a second embodiment of the present invention, particularly, a high electron mobility transistor (HEMT) having an AlGaN/GaN heterojunction.

In FIG. 4, there are shown a substrate 1, an intrinsic GaN layer 2, an Si-doped GaN layer 2a, and an AlGaN layer 3 which forms a heterojunction cooperatively with the doped GaN layer 2a. A two-dimensional electron gas is present in the GaN layer 2a in the vicinity of a heterojunction interface between the AlGaN layer 3 and the GaN layer 2a. The substrate 1 is composed of a material selected from sapphire, SiC, LiAlO₂, LiGaO₂ and the like. In general, an HEMT having a doped channel layer provides a higher maximum electric current and a higher power than an HEMT having an undoped channel layer (e.g., the HEMT according to the first embodiment).

In FIG. 4, there are also shown a gate electrode 4, a source 5, a drain 6, a source electrode 7 and a drain electrode 8. The transistor is connected to an external device through the source electrode 7 and the drain electrode 8. The gate electrode 4 controls the amount of an electric current flowing from the source 5 to the drain 6.

An explanation will be given to a source/drain contact formation method for production of the aforesaid semiconductor device.

As shown in FIG. 5, Si and Ti are simultaneously deposited selectively in contact formation regions in which ohmic contacts are to be formed on the AlGaN layer 3, and then Ti is deposited on the resulting layer, whereby a thin Si film 9 and a thin Ti film 10 are formed in contact with the AlGaN layer 3 and the thin Si film 9 is covered with the thin Ti film 10. In turn, the substrate 1 formed with these films 9, 10 is annealed at a high temperature (about 1000° C.) in a 100% nitrogen atmosphere for about 5 minutes.

By the high temperature heat treatment, the same structure as in the first embodiment (see FIG. 2(b)) is formed in the contact formation regions (the regions of the source 5 and the drain 6 shown in FIG. 4). Thus, the contact formation regions each have an excellent low-resistance ohmic characteristic.

The thin Si film 9 and the thin Ti film 10 thus deposited are completely consumed for the formation of the TiSi₂ portions and the TiN portions and the diffusion of Si, so that the need for the process for removing excess Si and Ti can be obviated.

In the method according to the second embodiment, the source/drain contacts each having a lower resistance and a more excellent ohmic characteristic can be formed through a process sequence with substantially the same number of process steps as that of the conventional method.

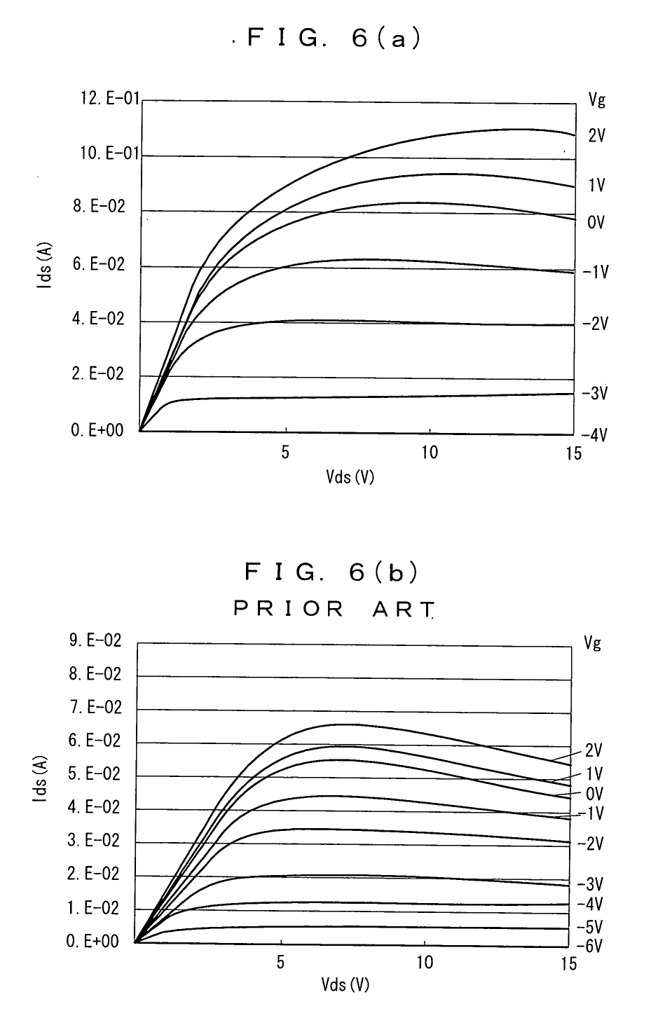

FIG. 6(a) illustrates an I-V characteristic of an HEMT having a doped channel and source/drain contacts formed by the method according to the second embodiment, and FIG. 6(b) illustrates an I-V characteristic of the HEMT having a doped channel and source/drain contacts formed by the conventional method (see FIG. 7).

As for the HEMT having the I-V characteristic shown in FIG. 6(a), the thickness of the substrate is 400 μm, the thickness of the GaN layer is 2 μm, the thickness of the AlGaN layer (Al/Ga=0.25/0.75) is 25 nm, the thickness of the thin Si film is 50 Å, the thickness of the thin Ti film is 150 Å, and the contact resistance is 1.5×10⁻⁶ Ωcm².

As for the HEMT having the I-V characteristic shown in FIG. 6(b), the thickness of the substrate is 400 μm, the thickness of the GaN layer is 2 μm, the thickness of the AlGaN layer (Al/Ga=0.25/0.75) is 25 nm, the thickness of the Ti film is 200 Å, the thickness of the Al film is 2000 Å, the thickness of the Au film is 2000 Å, and the contact resistance is 2×10⁻⁵ Ωcm². The substrate and the film formation regions of the HEMT of FIG. 6(b) have the same dimensions as those of the HEMT of FIG. 6(a).

As apparent from FIGS. 6(a) and 6(b), the HEMT according to the second embodiment is more excellent in output characteristics with a lower resistance in a linear area at the same gate voltage and with a higher drain electric current in a saturated area than the conventional HEMT.

The thin Ti film 10 is formed on the thin Si film 9 in the first embodiment, and the thin Ti film 10 is formed on and beside the thin Si film 9 in the second embodiment. However, an Si/Ti mixed film may be formed, as long as Si is present in an elemental form in the film.

According to the present invention, the film comprising Si and Ti is formed on the nitride semiconductor and then the film and the nitride semiconductor are heat-treated as described above, whereby an ohmic contact having a lower resistance and a more excellent ohmic characteristic can be formed by the inventive contact formation method without increasing the number of process steps as compared with the conventional contact formation method.

1. An ohmic contact formation method comprising:
forming a film comprising Si and Ti on a surface of a layer of a Group III nitride semiconductor; and
heat-treating the film and the semiconductor layer thereby diffusing Si as a dopant in the semiconductor layer.

2. The contact formation method as set forth in claim 1, wherein the film formation is performed by depositing Si and Ti in this order.

3. The contact formation method as set forth in claim 1, wherein a heat treatment temperature is in the range of 500° to 1100° C.

4. A semiconductor device comprising:
a Group III nitride semiconductor layer into which Si is diffused as an impurity by a heat treatment performed after a film comprising Si and Ti is formed on a surface of the Group III nitride semiconductor layer; and
an electrode film of TiSi₂ formed by a reaction between Ti and Si.
